(19) United States
(12) Patent Application Publication
(10) Pub. No.: US 2003/0060024 A1
(43) Pub. Date: Mar. 27, 2003

(54) Method of manufacturing semiconductor device

(75) Inventor: Yoshihisa Imori, Kanagawa (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/252,524

(22) Filed: Sep. 24, 2002

(30) Foreign Application Priority Data
Sep. 26, 2001 (JP) 2001-293749

(51) Int. Cl. H01L 21/46; H01L 21/78; H01L 21/301

(52) U.S. Cl. 438/460; 438/462

(57) ABSTRACT

A method of manufacturing a semiconductor device includes non-mechanically forming a groove along a dicing line in a surface of a semiconductor wafer, and cutting the semiconductor wafer along the dicing line to separate the semiconductor wafer into chips.

### CROSS REFERENCE TO RELATED APPLICATION

This application claims benefit of priority under 35USC §119 to Japanese patent application No. 2001-293749, filed on Sep. 26, 2001, the contents of which are incorporated by reference herein.

### BACKGROUND OF THE INVENTION

1. Field of the Invention

The present invention generally relates to a method of manufacturing a semiconductor device, which is particularly used for a semiconductor wafer dicing process (a chip separating process).

2. Description of the Related Art

A process for manufacturing a semiconductor device includes a dicing work process for cutting a semiconductor wafer by means of a blade in order to separate the semiconductor wafer into chips after an element is formed.

Referring to FIG. 12, a conventional dicing work process will be described below. In each of drawing which will be shown later, the same reference numbers are given to the same portions and repetitive explanations thereof are suitably omitted.

As shown in FIG. 12, a semiconductor wafer W is separated into chips by being cut in a direction of arrow from the element forming surface of the semiconductor wafer W by means of a blade BL. Dicing lines are determined on the basis of the array of elements formed on the semiconductor wafer W. A dicing tape DT is stuck on the surface (reverse surface) opposite to the element forming surface of the semiconductor wafer W, so as to prevent the chips from flying after the semiconductor wafer W is separated into the chips.

However, in the conventional dicing work process, there are following problems.

That is, as shown by broken line portions CP1 through CP4 in FIG. 12, chipping is easily caused by mechanical damage due to the blade BL during cutting. Such chipping occurs along the edges of the dicing lines on the worked surface and non-worked surface of the semiconductor wafer W, and it does not only cause chip failure in appearance, but it also causes the deterioration of the mechanical strength of the chips. Particularly as a notch CR in the broken line portion CP4 in FIG. 12, chipping may cause cracks. Conventionally, such chipping has been reduced by adjusting working conditions on process.

In addition, as shown in FIG. 12, when the dicing tape DT is previously stuck before the dicing work, it is required to cut the tape DT itself when the semiconductor wafer W is separated into the chips. Thus, tape scraps are caught on the edge of the blade BL during cutting. As a result, working blurring and/or loading on the edge of the blade occurs during cutting, which may effect chipping to be more accelerated.

### BRIEF SUMMARY OF THE INVENTION

According to a first aspect of the present invention, there is provided a method of manufacturing a semiconductor device comprising: non-mechanically forming a groove along a dicing line in a surface of a semiconductor wafer; and cutting the semiconductor wafer along the dicing line to separate the semiconductor wafer into chips.

According to a second aspect of the present invention, there is provided a method of manufacturing a semiconductor device comprising: forming a groove along a dicing line in a surface of a semiconductor wafer, the groove preventing chipping during dicing of the semiconductor wafer; and cutting the semiconductor wafer along the dicing line to separate the semiconductor wafer into chips.

### BRIEF DESCRIPTION OF THE DRAWINGS

FIG. 1 is a schematic plan view of a semiconductor wafer for use in a first embodiment of a semiconductor device according to the present invention;

FIG. 2 is a partially enlarged view of the semiconductor wafer shown in FIG. 1;

FIG. 3 is a schematic sectional view of the semiconductor wafer shown in FIG. 1;

FIG. 4 is a schematic sectional view showing a method of setting a position of an edge of a blade during a cutting work;

FIG. 5 is a schematic sectional view showing a dicing work process when a dicing tape is used;

FIG. 6 is a schematic sectional view showing chipping preventing grooves which are formed in both surfaces of an element forming surface and a reverse surface;

FIG. 7 is a schematic sectional view showing a chipping preventing groove having a side face perpendicular to the surface of a semiconductor wafer;

FIGS. 8A and 8B are illustrations for explaining a second embodiment of a method of manufacturing a semiconductor device according to the present invention;

FIGS. 9 and 10 are illustrations for explaining a third embodiment of a method of manufacturing a semiconductor device according to the present invention;

FIG. 11 is an illustration for explaining a third embodiment of a method of manufacturing a semiconductor device according to the present invention; and

FIG. 12 is a schematic sectional view showing an example of a conventional dicing work method.

### DETAILED DESCRIPTION OF THE INVENTION

Referring now to the accompanying drawings, some of embodiments of the present invention will be described below.

(1) First Embodiment

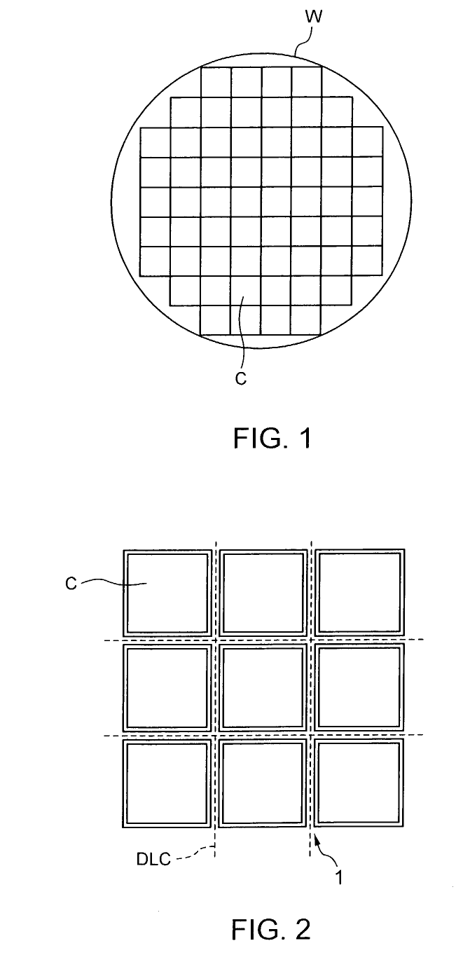

FIG. 1 is a plan view of a semiconductor wafer W which is an object to be processed by a method of manufacturing a semiconductor device in this embodiment, and FIG. 2 is a partially enlarged view of FIG. 1. FIGS. 1 and 2 are plan views which are viewed from a surface (non-worked surface) opposite to the element forming surface of the semiconductor wafer W.

As shown in FIG. 2, in the manufacturing method in this embodiment, grooves (which will be hereinafter referred to as chipping preventing grooves) 1 for preventing chipping are previously formed along dicing line centers DLC on the non-worked surface of the semiconductor wafer W. The chipping preventing grooves 1 can be formed by an etching work, such as the RIE (Reactive Ion Etching), or a laser beam machining in a semiconductor wafer process prior to a cutting work.

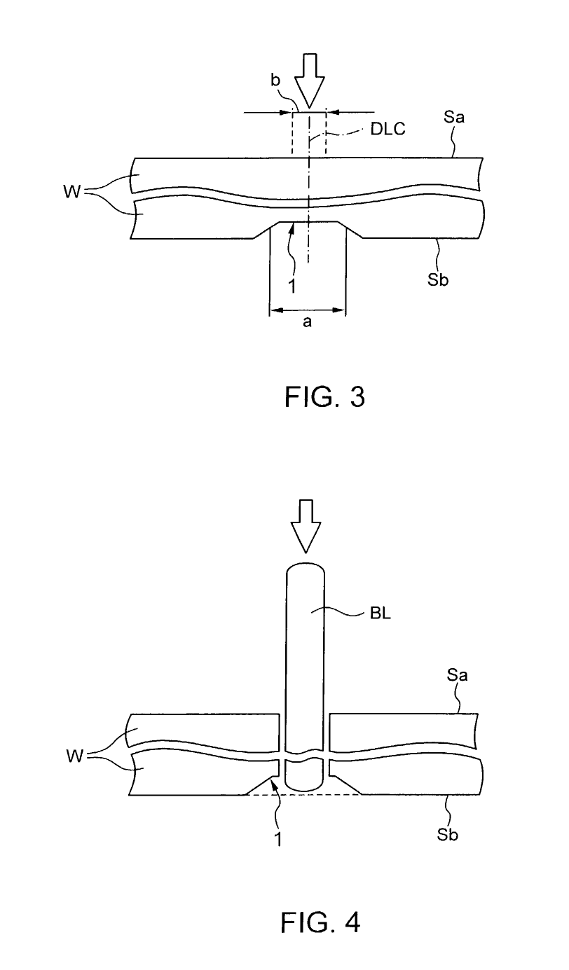

FIG. 3 is a sectional view of the semiconductor wafer W shown in FIG. 1, and a sectional view taken along a line perpendicular to the dicing lines. As shown in this figure, the chipping preventing groove 1 is formed so as to have a bottom face, which is parallel to a non-worked surface Sb opposite to a worked surface Sa, and a tapered side wall, and so as to have a wider width a than an actual semiconductor wafer cutting width b. Specifically, it has been revealed that it is possible to obtain good results if the width a of the chipping preventing groove 1 is wider than the semiconductor wafer cutting width b by about 5 ìm to about 50 ìm.

Then, as shown in FIG. 4, the semiconductor wafer W is cut along the dicing center lines DLC by means of a blade BL. At this time, as shown in FIG. 4, a cutting work is carried out after the position of the edge of the blade BL is set so that the tip of the blade BL is not deeper than the position between the bottom face of the chipping preventing groove 1 and the non-worked surface Sb.

Thus, according to this embodiment, the chipping preventing groove 1 is previously formed along the dicing line, and the semiconductor wafer W is cut so that the blade passes through the bottom face of the chipping preventing groove 1. Therefore, the strength of the semiconductor wafer W on the non-worked surface Sb opposite to the element forming surface is improved, so that the occurrence of chipping due to dicing can be stopped in the chipping preventing groove 1. Thus, it is possible to prevent the influence of chipping on an element pattern on the semiconductor wafer w. In addition, since the chipping preventing groove 1 is formed so as to have the wider width a than the cutting width b, chipping can be stopped on the bottom of the groove even if the center is shifted by the variation in work precision. Moreover, since the bottom of the chipping preventing groove 1 is formed so as to be parallel to the non-worked surface Sb of the semiconductor wafer, chipping can be stopped in the groove by the edge of the corner portion.

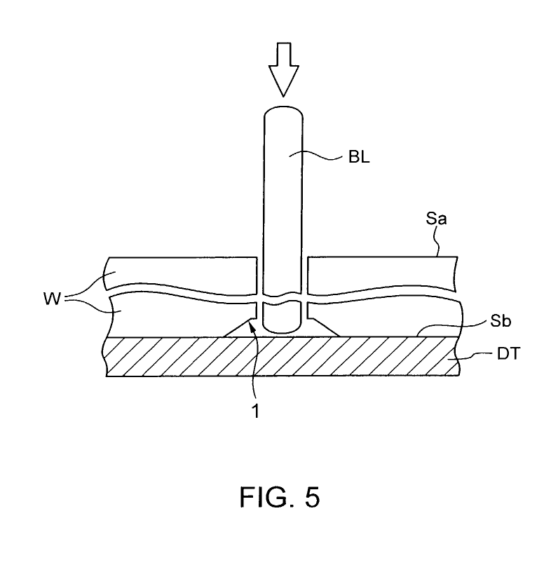

FIG. 5 shows a dicing work process when a dicing tape DT is stuck on the non-worked surface Sb. Also in this case, similar to the case shown in FIG. 4, the semiconductor wafer W is worked without cutting the dicing tape DT, by setting the deepest position of the edge of the blade BL between the bottom face of the chipping preventing groove 1 and the non-worked surface Sb of the semiconductor wafer W. Thus, no tape scraps are caught on the edge of the blade, so that it is possible to prevent chipping from being caused by working blurring and/or loading on the edge of the blade.

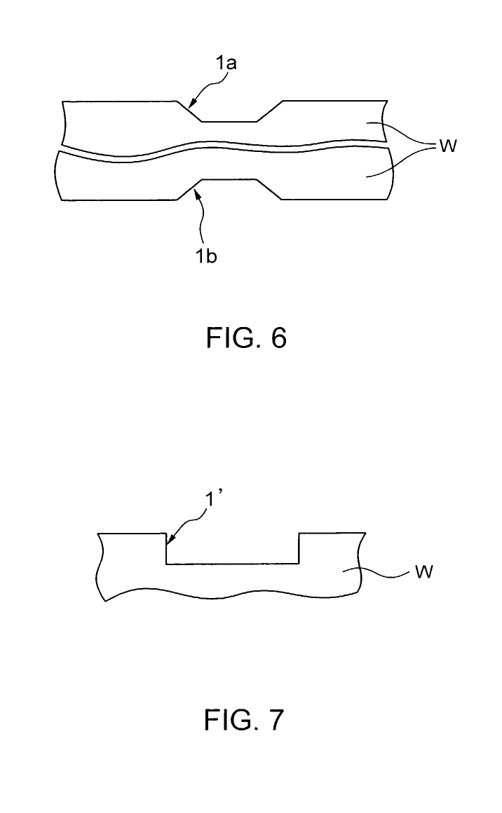

While the chipping preventing grooves 1 have been formed in the surface opposite to the element forming surface of the semiconductor wafer W in the above described embodiment, the chipping preventing grooves 1 may be formed in the element forming surface. In this case, the chipping preventing grooves 1 may be formed by an etching work before the reverse surface is ground. In addition, the ground surface should not be limited to one side, but chipping preventing grooves 1a and 1b may be formed in both surfaces of the element forming surface and reverse surface as shown in FIG. 6. In this case, it is possible to further improve the strength of the chips.

The cross-sectional shape of the chipping preventing groove should not be limited to that having the tapered side face. For example, as a chipping preventing groove 1′ shown in FIG. 7, a chipping preventing groove may be formed so as to have a side face substantially perpendicular to the surface of the semiconductor wafer W.

Thus, according to this embodiment, the chipping preventing grooves are previously formed along the dicing lines, so that it is possible to provide a difference in level from the surface of the semiconductor wafer. Thus, even if chipping occurs, the chipping can be stopped in the chipping preventing groove, so that it is possible to prevent the influence of the chipping on the surface of the semiconductor wafer.

In addition, when the dicing tape DL is used, it is possible to control the cutting depth during cutting by utilizing a cavity between the tape DL and the semiconductor wafer W.

(2) Second Embodiment

When forming a chipping preventing groove 1 only on an element forming surface, the strength of the chip on a surface from which no dicing is carried out is in general inferior to a surface from which dicing is carried out. Therefore, it is preferable to set a dicing work surface on the reverse surface which is opposite to the element forming surface. In this case, it is required to assign dicing lines.

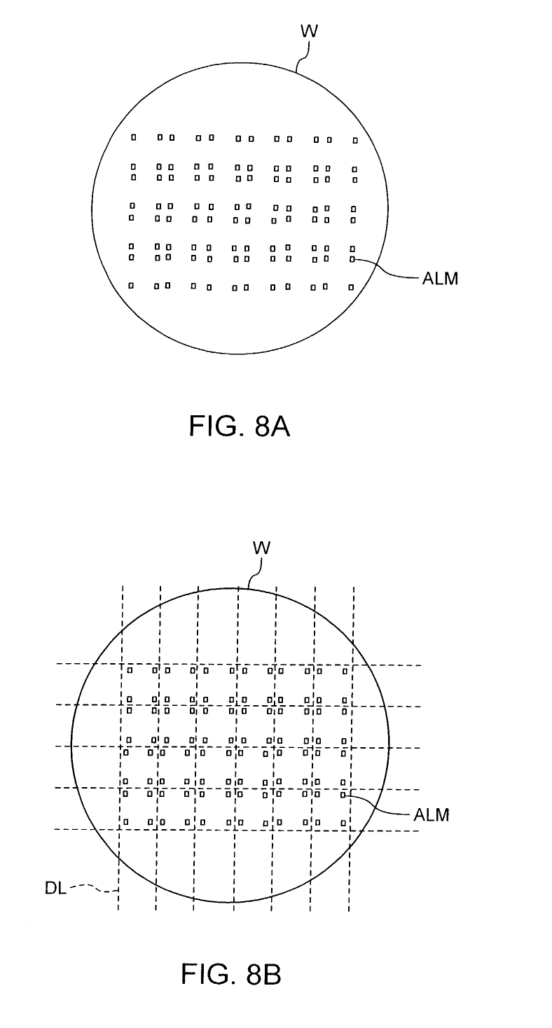

Referring to FIGS. 8A and 8B, a dicing line assigning method in such a case will be described below.

First, as shown in FIG. 8A, alignment marks ALM are previously formed on the reverse surface of the semiconductor wafer W by means of a connecting through plug or the like which is used for a three-dimensional stacked chip structure (COC; Chip on Chip).

Then, as shown in FIG. 8B, the mage of the reverse surface is picked up by an image pick-up device (not shown), and dicing lines DL are detected by an image processing. Thus, the positions of dicing line centers (work centers) are determined, and dicing is carried out from the reverse surface of the semiconductor wafer to separate the wafer into chips. Furthermore, when the dicing tape DL is used, the cutting depth of the edge during dicing is set so as not to cut the tape DL (see FIG. 5).

Thus, according to this embodiment, the alignment marks ALM formed on the reverse surface of the semiconductor wafer are utilized, so that the positions of the dicing lines DL can be easily detected. Thus, the dicing can be easily from the reverse surface of the semiconductor wafer, so that the chipping on the side of the reverse surface of the semiconductor wafer, which is conventionally caused by the dicing work after grinding the reverse surface of the semiconductor wafer, can be suppressed to the minimum. Moreover, an intermediate process after grinding the reverse surface of the semiconductor wafer, such as the re-sticking of wafer holding tapes on the surface and reverse surface of the semiconductor wafer, can be omitted, so that it is possible to carry out continuous works.

(3) Third Embodiment

In this embodiment, the above described chipping preventing grooves are utilized for a previous dicing.

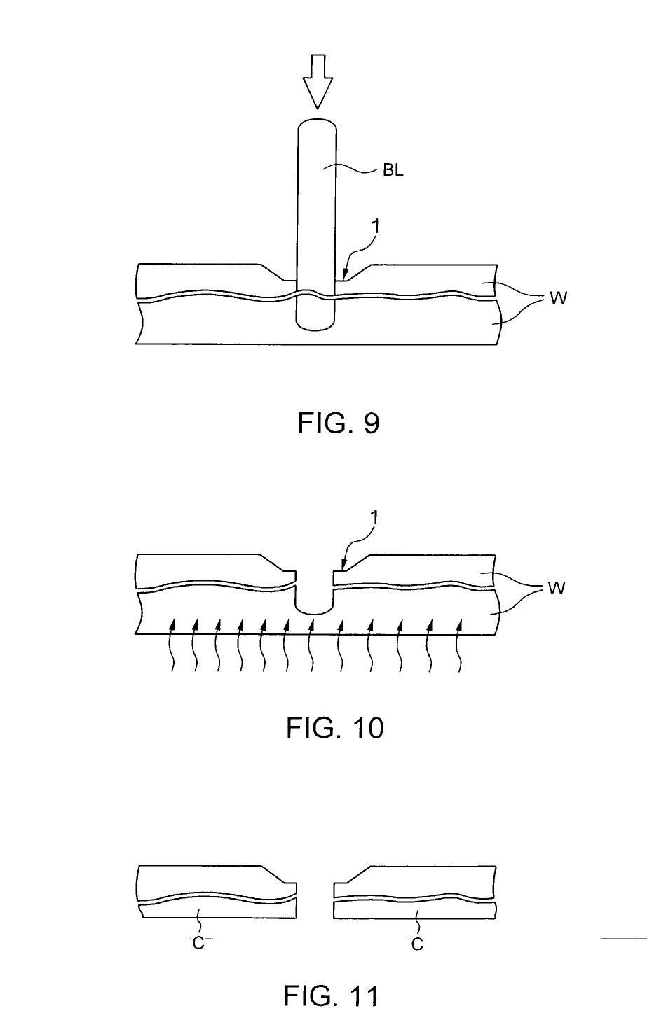

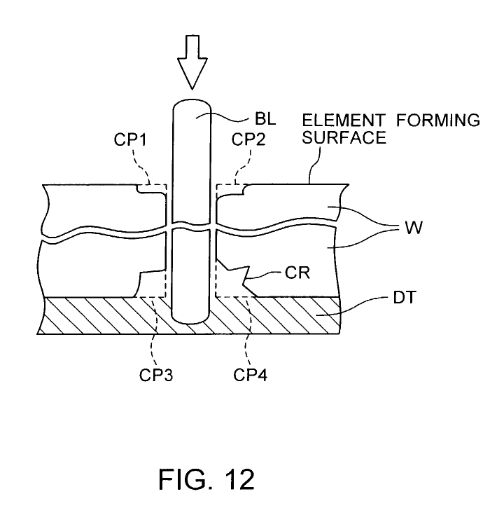

First, as shown in FIG. 9, a semiconductor wafer W, on which chipping preventing grooves 1 have been formed in an element forming surface, is cut so that the edge of a blade BL reaches a depth which corresponds to or deeper than the final thickness of chips.

Then, as shown in FIG. 10, the reverse surface of the semiconductor wafer W is retracted until the semiconductor wafer W has the final thickness of chips by the etching work, such as the RIE.

By the above described processes, as shown in FIG. 11, the semiconductor wafer W is separated into chips.

Thus, according to this embodiment, only by forming the chipping preventing grooves 1 only in the element forming surface, chipping can be suppressed to the minimum.

What is claimed is:

1. A method of manufacturing a semiconductor device comprising:
non-mechanically forming a groove along a dicing line in a surface of a semiconductor wafer; and
cutting the semiconductor wafer along the dicing line to separate the semiconductor wafer into chips.

2. A method of manufacturing a semiconductor device according to claim 1, wherein said groove is formed in one or both of a worked surface, from which the semiconductor wafer is to be cut, and a non-worked surface which is opposite to said worked surface.

3. A method of manufacturing a semiconductor device according to claim 1, wherein said groove is formed in an element forming surface of the semiconductor wafer, and which further comprises:
providing an alignment mark on a surface opposite to said element forming surface of the semiconductor wafer, the alignment mark being used for assigning the dicing line; and
detecting the dicing line using said alignment mark,
the semiconductor wafer being cut along the detected dicing line to be separated into chips.

4. A method of manufacturing a semiconductor device according to claim 1, wherein said groove is formed in at least a non-worked surface opposite to a worked surface from which the semiconductor wafer is to be cut,
the semiconductor wafer is cut by means of a blade, and
said separating the semiconductor wafer into chips includes setting a depth to which an edge of a blade reaches during cutting between a bottom surface of said groove, which is formed in said non-worked surface of the semiconductor wafer, and said non-worked surface of the semiconductor wafer.

5. A method of manufacturing a semiconductor device according to claim 1, which further comprises sticking a dicing tape on a non-worked surface opposite to a worked surface which is a cut surface of the semiconductor wafer, and wherein
the semiconductor wafer is cut by means of a blade, and
said separating the semiconductor wafer into chips includes setting a depth to which an edge of the blade reaches during cutting in front of said dicing tape viewed from said worked surface.

6. A method of manufacturing a semiconductor device according to claim 1, wherein said groove is formed in an element forming surface of the semiconductor wafer, and
said separating the semiconductor wafer into chips includes cutting the semiconductor wafer along the dicing line by a depth which corresponds to or deeper than a desired thickness of chips, and retracting a surface opposite to said element forming surface of the semiconductor wafer until the semiconductor wafer is separated into chips.

7. A method of manufacturing a semiconductor device according to claim 1, wherein said groove has a wider width than a cut width of the semiconductor wafer.

8. A method of manufacturing a semiconductor device according to claim 1, wherein a bottom surface of said groove is substantially parallel to a surface of the semiconductor wafer.

9. A method of manufacturing a semiconductor device according to claim 1, wherein said non-mechanical forming of said groove is carried out by a reactive ion etching.

10. A method of manufacturing a semiconductor device according to claim 1, wherein said non-mechanical forming of said groove is carried out by means of a laser.

11. A method of manufacturing a semiconductor device comprising:
forming a groove along a dicing line in a surface of a semiconductor wafer, said groove preventing chipping during dicing of the semiconductor wafer; and
cutting the semiconductor wafer along the dicing line to separate the semiconductor wafer into chips.

12. A method of manufacturing a semiconductor device according to claim 11, wherein said groove is formed in one or both of a worked surface, from which the semiconductor wafer is to be cut, and a non-worked surface which is opposite to said worked surface.

13. A method of manufacturing a semiconductor device according to claim 11, wherein said groove is formed in an element forming surface of the semiconductor wafer, and which further comprises:
providing an alignment mark on a surface opposite to said element forming surface of the semiconductor wafer, said alignment mark being used for assigning the dicing line; and
detecting the dicing line using said alignment mark,
the semiconductor wafer being cut along the detected dicing line to be separated into chips.

14. A method of manufacturing a semiconductor device according to claim 11, wherein said groove is formed in at least a non-worked surface opposite to a worked surface from which the semiconductor wafer is to be cut,
the semiconductor wafer is cut by means of a blade, and
said separating the semiconductor wafer into chips includes setting a depth to which an edge of a blade reaches during cutting between a bottom surface of said groove, which is formed in said non-worked surface of the semiconductor wafer, and said non-worked surface of the semiconductor wafer.

15. A method of manufacturing a semiconductor device according to claim 11, which further comprises sticking a dicing tape on a non-worked surface opposite to a worked surface which is a cut surface of the semiconductor wafer, and wherein
the semiconductor wafer is cut by means of a blade, and
said separating the semiconductor wafer into chips includes setting a depth to which an edge of the blade reaches during cutting in front of said dicing tape viewed from said worked surface.

16. A method of manufacturing a semiconductor device according to claim 11, wherein said groove is formed in an element forming surface of the semiconductor wafer, and
said separating the semiconductor wafer into chips includes cutting the semiconductor wafer along the dicing line by a depth which corresponds to or deeper than a desired thickness of chips, and retracting a surface opposite to said element forming surface of the semiconductor wafer until the semiconductor wafer is separated into chips.

17. A method of manufacturing a semiconductor device according to claim 11, wherein said groove has a wider width than a cut width of the semiconductor wafer.

18. A method of manufacturing a semiconductor device according to claim 11, wherein a bottom surface of said groove is substantially parallel to a surface of the semiconductor wafer.

19. A method of manufacturing a semiconductor device according to claim 11, wherein said groove which prevents chipping is formed by a reactive ion etching.

20. A method of manufacturing a semiconductor device according to claim 11, wherein said groove which prevents chipping is formed by means of a laser.
